(19) United States
(12) Patent Application Publication
(10) Pub. No.: US 2013/0231038 A1
(43) Pub. Date: Sep. 5, 2013

(54) CONTAINER OF CLOUD COMPUTING SYSTEM

(71) Applicant: YAO-TING CHANG, Tu-Cheng (TW)

(72) Inventor: YAO-TING CHANG, Tu-Cheng (TW)

(73) Assignee: HON HAI PRECISION INDUSTRY CO., LTD., Tu-Cheng (TW)

(21) Appl. No.: 13/457,708

(22) Filed: Apr. 27, 2012

(30) Foreign Application Priority Data
Mar. 2, 2012 (TW) 101106879

(51) Int. Cl. H05K 5/00

(52) U.S. Cl. 454/184

(57) ABSTRACT

A container of a cloud computing system includes a housing defining a chamber, an airflow inlet and an airflow outlet, a fan fixed in the airflow inlet, and a dust gauze covering the airflow inlet. The airflow inlet and the airflow outlet both communicate with the chamber. The fan is capable of rotating clockwise or counter-clockwise by a controlling device. During the fan rotates clockwise, the fan draws exterior air into the chamber through the airflow inlet, and then air vents out of the chamber via the airflow outlet. During the fan rotates counter-clockwise, the fan draws the air in the chamber blow to the dust gauze via the airflow inlet to clear dust on the dust gauze.

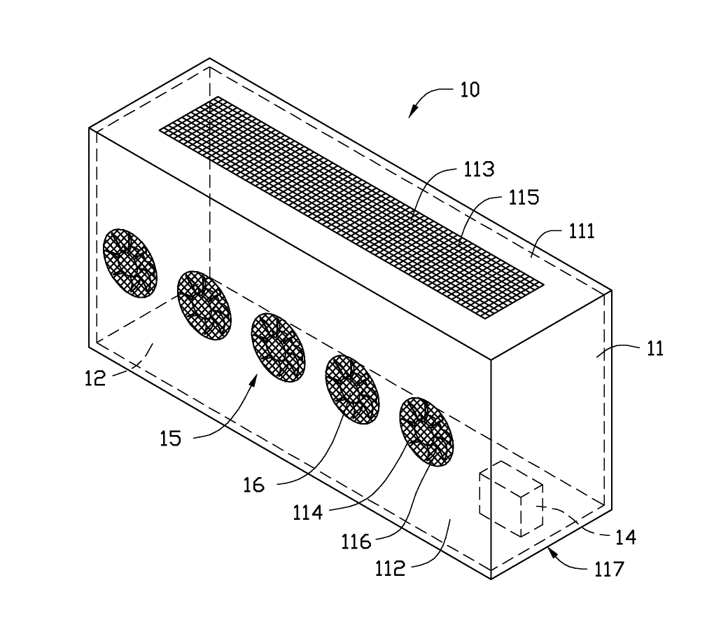

### BACKGROUND

1. Technical Field

The disclosure generally relates to containers of containing cloud computing systems, particularly to such a container of a cloud computing system with a ventilation system.

2. Description of Related Art

A cloud computing system typically includes a container and servers positioned in the container. To cool the servers in the container, the container generally includes a ventilation system used to draw exterior cool air into the container through an airflow inlet, and hot air in the container is vented out via an airflow outlet of the ventilation system. However, after a long-term use, a lot of dust may be accumulated at the airflow inlet, which is an adverse affect for cooling effect in the container.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary container of a cloud computing system. Moreover, in the drawings like reference numerals designate corresponding parts throughout the several views. Wherever possible, the same reference numbers are used throughout the drawings to refer to the same or like elements of an embodiment.

FIGURE is a schematic view of an embodiment of a container of a cloud computing system.

### DETAILED DESCRIPTION

Referring to the FIGURE, a container 10 of a cloud computing system includes a housing 11, a controlling device 14 and a fan assembly 15 mounted to the housing 11.

The housing 11 includes a lower board 117, an upper board 111 opposite to the lower board 117, and a side board 112 connecting the lower board 117 and the upper board 111. The lower board 117, upper board 111 and side board 112 cooperatively form a chamber 12, in which the controlling device 14 is received. An airflow outlet 113 is defined through the upper board 111 and communicates with the chamber 12. A dust strainer 115 covers the airflow outlet 113 to prevent impurities, such as dust, from entering into the chamber 12. A plurality of airflow inlets 114 are defined through the side board 112 and communicate with the chamber 12.

The fan assembly 15 includes a plurality of fans 16 equal to the airflow inlets 114. Each fan 16 is fixed in one of the airflow inlets 114. A plurality of dust gauzes 116 cover the airflow inlets 114 to prevent impurities, such as dust, from entering into the chamber 12. The fans 16 can rotate clockwise or counter-clockwise under a control of the controlling device 14. When the fans 16 rotate clockwise, the fans assembly 15 draws exterior cool air into the chamber 12 through the airflow inlets 114 and force the exterior cool air to flow to electronic devices inside the chamber 12, such as the controlling device 14, which are cooled. Hot air in the chamber 12 then vents out of the chamber 12 via the airflow outlet 113. When the fans 16 rotate counter-clockwise, the fans assembly 15 exhausts the air in the chamber 12 via the airflow inlets 114 to clear dust on the dust gauzes 116.

One example of cooling the chamber 12 is taken below. After the fans 16 all rotate clockwise to draw exterior cool air into the chamber 12 via the airflow inlets 114 to cooling the chamber 12 for a first determined period (e.g., about 60 minutes), the fans 16 all rotate counter-clockwise to draw air in the chamber 12 out of the chamber 12 via the airflow inlets 114 for a second determined period (e.g., about 1 minute), the air from the chamber 12 blows to the dust gauzes 116, and the dust accumulated on the dust gauzes 116 is cleared.

Another example of cooling the chamber 12 is taken below. After the fans 16 all rotate clockwise to draw exterior cool air into the chamber 12 to cooling the chamber 12 for the first determined period (e.g., about 60 minutes), at least one of the fans 16 rotates counter-clockwise to clear the dust on the dust gauze 116 corresponding to the at least one of the fans 16 for the second determined period (e.g., about 1 minute), simultaneously, the other fans 16 continue to rotate clockwise to cooling the chamber 12.

It is to be understood, however, that even through numerous characteristics and advantages of the disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A container of a cloud computing system, the container comprising:
a housing defining a chamber, an airflow inlet and an airflow outlet, the airflow inlet and the airflow outlet both communicating with the chamber;
a fan fixed in the airflow inlet;
a controlling device controlling the fan to rotate clockwise or counter-clockwise; and
a dust gauze covering the airflow inlet;
wherein during the fan rotates clockwise, the fan draws exterior air into the chamber through the airflow inlet, and air in the chamber is vent out of the chamber via the airflow outlet; during the fan rotates counter-clockwise, the fan draws the air in the chamber blow to the dust gauze via the airflow inlet to clear dust on the dust gauze.

2. The container as claimed in claim 1, wherein the housing includes a lower board, an upper board opposite to the lower board and a side board connecting the lower board and the upper board; the lower board, the upper board and the side board cooperatively forming a chamber.

3. The container as claimed in claim 2, wherein the airflow outlet is defined through the upper board.

4. The container as claimed in claim 3 wherein a dust strainer covers the airflow outlet to prevent impurities from entering into the chamber.

5. The container as claimed in claim 2 wherein the airflow inlet is defined through the side board.

6. The container as claimed in claim 1 wherein the controlling device is received in the chamber.

7. A container of a cloud computing system for containing electronic devices therein, the container comprising:
a housing defining a chamber, a plurality of airflow inlets and an airflow outlet, the airflow inlets and the airflow outlet both communicating with the chamber;
a fan assembly including a plurality of fans corresponding to the airflow inlets, the fans being capable of rotating clockwise or counter-clockwise; and
a dust gauze covering the airflow inlets;
wherein after the fans all rotate clockwise to draw exterior cool air into the chamber to cooling the chamber for a first determined period, at least one of the fans rotates counter-clockwise to draw air from the chamber blow to the dust gauze to clear dust on the dust gauze corresponding the at least one of the fans for a second determined period.

8. The container as claimed in claim 7, wherein the housing includes a lower board, an upper board opposite to the lower board, and a side board connecting the lower board and the upper board; the lower board, the upper board and the side board cooperatively forming a chamber.

9. The container as claimed in claim 8, wherein the airflow outlet is defined through the upper board.

10. The container as claimed in claim 9 wherein a dust strainer covers the airflow outlet to prevent impurities from entering into the chamber.

11. The container as claimed in claim 8 wherein the airflow inlets are defined through the side board.

12. The container as claimed in claim 7 wherein a controlling device controls the fans to rotate clockwise or counter-clockwise.

13. The container as claimed in claim 7, wherein the second determined period is shorter than the first determined period.
